(19) United States
(12) Patent Application Publication
(10) Pub. No.: US 2025/0384544 A1
(43) Pub. Date: Dec. 18, 2025

(54) MONITORING METHOD AND MANUFACTURING APPARATUS

(71) Applicant: SCREEN Holdings Co., Ltd., Kyoto (JP)

(72) Inventor: Satoshi OKAMOTO, Kyoto-shi, Kyoto (JP)

(21) Appl. No.: 18/867,548

(22) PCT Filed: Jun. 9, 2023
(86) PCT No.: PCT/JP2023/021584

§ 371 Date: Nov. 20, 2024

(30) Foreign Application Priority Data
Jun. 17, 2022 (JP) 2022-098066

(51) Int. Cl. G06T 7/00; G01N 21/55; G06T 7/521; H04N 25/47

(52) U.S. Cl. CPC G06T 7/0006; G01N 21/55; G06T 7/521; H04N 25/47; G06T 2207/10152; G06T 2207/30148

(57) ABSTRACT

An image of a processing fluid is captured while the processing fluid is supplied to a substrate W that is as an object to be processed. At this time, an irradiator applies pattern light having a light and dark pattern, and a camera captures a reflected image or projected image of the pattern light on the surface of the processing fluid. Then, the fluid state of the processing fluid is evaluated based on the result of image capture by the camera. Since the processing fluid is imaged together with the pattern light, it is possible to detect minute changes in the fluid state of the processing fluid in accordance with distortion of the pattern light.

### TECHNICAL FIELD

The present invention relates to a monitoring method for monitoring a processing unit and a manufacturing apparatus.

### BACKGROUND ART

In apparatuses that perform precise and fine machining on substrates such as semiconductor wafers, slight variations in operation can be a cause of significant decrease in product quality. Thus, technology is conventionally known in which a camera is installed in an apparatus and monitors anomalies in operation. For example, Patent Literature (PTL) 1 describes capturing processes for processing substrates by a camera and detecting the occurrence of anomalies on the basis of captured moving images.

### CITATION LIST

### Patent Literature

PTL 1: Japanese Patent Application Laid-Open No. 2013-165607

### SUMMARY OF INVENTION

### Technical Problem

Substrate cleaning devices called spin processors supply a processing fluid from nozzles to upper surfaces of substrates that are rotating at high speed. The fluid state of this processing fluid varies depending on events such as drive errors of a pump or nozzle vibrations. Such a change in the fluid state of the processing fluid may cause unevenness or insufficiency of processing on substrates. For this reason, the cleaning devices are required to monitor whether the fluid state of the processing fluid supplied to the substrates is normal. However, the processing fluid supplied to the substrates is colorless and transparent and flows at high speed. Therefore, it is difficult to capture minute changes in the fluid state of the processing fluid by the camera.

The present invention has been made in light of such circumstances, and it is an object of the present invention to provide a technique for detecting minute changes in the fluid state of a processing fluid.

### Solution to Problem

To solve the problem described above, a first aspect of the present application is a monitoring method for monitoring a processing unit that supplies a processing fluid to an object to be processed. The monitoring method includes a) capturing an image of the processing fluid while supplying the processing fluid to the object to be processed, and b) evaluating a fluid state of the processing fluid in accordance with a result of image capture in the operation a). In the operation a), pattern light having a light and dark pattern is applied to capture a reflected image or projected image of the pattern light on the surface of the processing fluid.

A second aspect of the present application is the monitoring method according to the first aspect, in which in the operation a), the image of the processing fluid is captured by an event-based camera to acquire event data configured by information only about a pixel with a changed luminance value, and in the operation b), the fluid state of the processing fluid is evaluated based on the event data.

A third aspect of the present application is the monitoring method according to the first or second aspect, in which in the operation a), the reflected image of the pattern light reflected on the surface of the processing fluid is captured.

A fourth aspect of the present application is the monitoring method according to the first or second aspect, in which in the operation a), the projected image of the pattern light projected on the surface of the processing fluid is captured.

A fifth aspect of the present application is the monitoring method according to the first or second aspect, in which in the operation a), the pattern light is applied to a projection surface that is different from the object to be processed, to capture the reflected image of the projection surface reflected on the surface of the processing fluid.

A sixth aspect of the present application is the monitoring method according to any one of the first to fifth aspects, in which the light and dark pattern is a pattern in which a bright region and a dark region are alternately and repeatedly aligned in one direction.

A seventh aspect of the present application is the monitoring method according to any one of the first to fifth aspects, in which the light and dark pattern includes a pattern in which a bright region and a dark region are alternately and repeatedly aligned in two directions orthogonal to each other.

An eighth aspect of the present application is the monitoring method according to any one of the first to seventh aspects, in which the object to be processed is a semiconductor wafer.

A ninth aspect of the present application is a manufacturing apparatus that includes a nozzle from which a processing fluid is supplied to an object to be processed, an irradiator that applies pattern light having a light and dark pattern, a camera that captures an image of the processing fluid supplied from the nozzle to the object to be processed, and a computer communicably connected to the camera. The irradiator applies the pattern light, and the camera captures a reflected image or projected image of the pattern light on the surface of the processing fluid. The computer evaluates a fluid state of the processing fluid in accordance with a result of image capture by the camera.

### Advantageous Effects of Invention

According to the first to ninth aspects of the present application, the processing fluid is imaged together with the pattern light. Accordingly, it is possible to detect minute changes in the fluid state of the processing fluid on the basis of distortion of the pattern light.

In particular, according to the second aspect of the present application, high-speed motion of the processing fluid can be imaged by the event-based camera. Besides, since the event data is data only about pixels with changed luminance values, there is no need to separately perform processing for extracting locations where the pattern light has changed.

In particular, according to the third aspect of the present application, even in the case where the projected image of the pattern light is difficult to appear on the surface of the processing fluid, it is possible to evaluate the fluid state of the processing fluid on the basis of the reflected image.

In particular, according to the fourth aspect of the present application, even in the case where the pattern light is difficult to be reflected on the surface of the processing fluid, it is possible to evaluate the fluid state of the processing fluid on the basis of the projected image.

In particular, according to the fifth aspect of the present application, the irradiator that applies the pattern light has a higher degree of flexibility in its positioning.

### BRIEF DESCRIPTION OF DRAWINGS

FIG. 1 is a plan view of a substrate processing apparatus.

FIG. 2 is a longitudinal sectional view of a processing unit.

FIG. 3 is a perspective view of a substrate holder, an irradiator, and an event-based camera.

FIG. 4 is a diagram showing an example of a light and dark pattern of pattern light.

FIG. 5 is a diagram showing another example of the light and dark pattern of the pattern light.

FIG. 6 is a diagram showing another example of the light and dark pattern of the pattern light.

FIG. 7 is a block diagram showing connection between a controller and each consistent element of a processing unit.

FIG. 8 is a flowchart showing a procedure of substrate processing.

FIG. 9 is a flowchart showing a procedure of monitoring processing.

FIG. 10 is a diagram showing image capture by the event-based camera.

FIG. 11 is a diagram showing image capture by the event-based camera.

FIG. 12 is a diagram showing an example of a frame image.

FIG. 13 is a diagram showing an example of imaging event data.

FIG. 14 is a diagram showing image capture according to a variation.

### DESCRIPTION OF EMBODIMENT

An embodiment of the present invention is described hereinafter with reference to the drawings.

### 1. Overall Configuration of Substrate Processing Apparatus

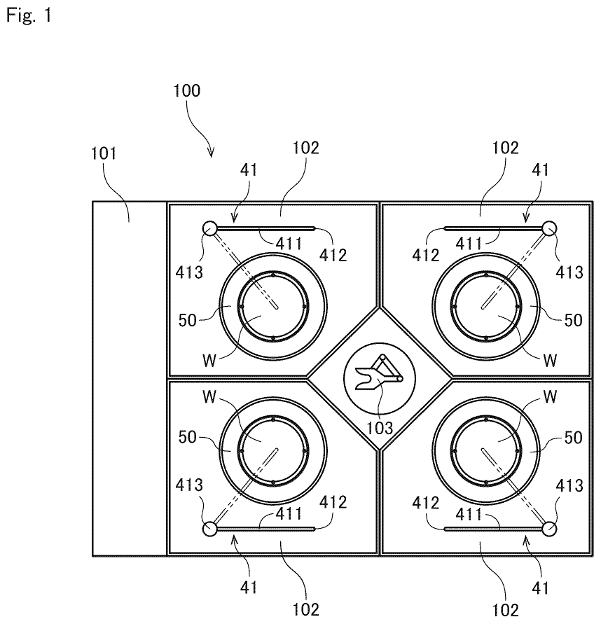

FIG. 1 is a plan view of a substrate processing apparatus 100 as one example of a manufacturing apparatus according to the present invention. The substrate processing apparatus 100 is an apparatus that processes surfaces of disk-like substrates W (semiconductor wafers) by supplying a processing fluid to the surfaces of the substrates W in the process of manufacturing the semiconductor wafers. As shown in FIG. 1, the substrate processing apparatus 100 includes an indexer 101, a plurality of processing units 102, and a main transport robot 103.

The indexer 101 is a part for transporting substrates W that have not been processed from the outside into the apparatus and transporting processed substrates W to the outside of the apparatus. The indexer 101 includes a plurality of carriers arranged to house a plurality of substrates W. The indexer 101 also includes a transfer robot, which is not shown. The transfer robot transfers substrates W between the carriers of the indexer 101 and the processing units 102 or the main transport robot 103.

The processing units 102 are so-called sheet-fed processing parts that process substrates W, which are objects to be processed, one by one. The processing units 102 are arranged around the main transport robot 103. In the present embodiment, three layers each including four processing units 102 arranged around the main transport robot 103 are laminated one above another in the height direction. That is, the substrate processing apparatus 100 according to the present embodiment includes a total of 12 processing unit 102. A plurality of substrates W are processed in parallel in each processing unit 102. The number of processing units 102 included in the substrate processing apparatus 100 is not limited to 12 and may, for example, be one, four, eight, or 24.

The main transport robot 103 is a mechanism for transporting substrates W between the indexer 101 and the processing units 102. For example, the main transport robot 103 may include a hand that holds substrates W and an arm that moves the hand. The main transport robot 103 takes out substrates W that have not been processed from the indexer 101 and transports the substrates W to the processing units 102. When the processing of substrates W in the processing units 102 is completed, the main transport robot 103 takes out the processed substrates W from the processing units 102 and transports the processed substrates W to the indexer 101.

### 2. Configuration of Processing Units

Next, a detailed configuration of the processing units 102 is described. While the following description is given of one of the processing units 102 included in the substrate processing apparatus 100, the other processing units 102 also have equivalent configurations.

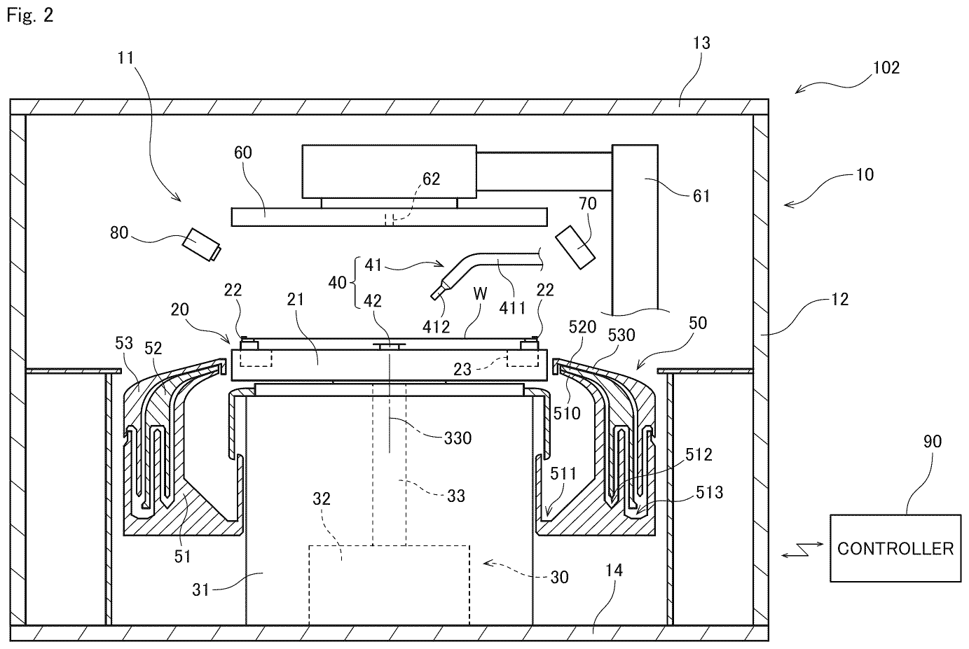

FIG. 2 is a longitudinal sectional view of one processing unit 102. As shown in FIG. 2, the processing unit 102 includes a chamber 10, a substrate holder 20, a rotation mechanism 30, a processing fluid supplier 40, a processing fluid collector 50, a barrier plate 60, an irradiator 70, an event-based camera 80, and a controller 90.

The chamber 10 is a casing that includes a processing space 11 for processing a substrate W. The chamber 10 has a side wall 12 that surrounds the lateral side of the processing space 11, a top plate 13 that covers the top of the processing space 11, and a bottom plate 14 that covers the bottom of the processing space 11. The substrate holder 20, the rotation mechanism 30, the processing fluid supplier 40, the processing fluid collector 50, the barrier plate 60, the irradiator 70, and the event-based camera 80 are housed inside the chamber 10. Part of the side wall 12 has a transport entrance for transporting a substrate W into and out of the chamber 10, and a shutter that opens and closes the transport entrance.

The substrate holder 20 is a mechanism for holding a substrate W horizontally (in a position in which the normal faces a vertical direction) inside the chamber 10. As shown in FIG. 2, the substrate holder 20 includes a disk-like spin base 21 and a plurality of chuck pins 22. The chuck pins 22 are provided at equiangular intervals along the outer periphery of the upper surface of the spin base 21. A substrate W is held by the chuck pins 22, with its to-be-processed surface on which the pattern is formed facing upward. Each chuck pin 22 comes in contact with the lower surface of the peripheral portion of the substrate W and the outer peripheral end face of the substrate W and supports the substrate W at a position spaced above from the upper surface of the spin base 21 with slight clearance therebetween.

The spin base 21 includes a chuck-pin switching mechanism 23 for switching the positions of the chuck pins 22. The chuck-pin switching mechanism 23 switches the chuck pins 22 between a chucking position at which a substrate W is held and a de-chucking position at which hold of a substrate W is released.

The rotation mechanism 30 is a mechanism for rotating the substrate holder 20. The rotation mechanism 30 is housed inside a motor cover 31 provided below the spin base 21. As indicated by broken lines in FIG. 2, the rotation mechanism 30 includes a spin motor 32 and a support shaft 33. The support shaft 33 extends in the vertical direction and has a lower end connected to the spin motor 32 and an upper end fixed to the center of the spin base 21. When the spin motor 32 is driven, the support shaft 33 rotates about the shaft center 330. The substrate holder 20 and the substrate W held by the substrate holder 20 also rotate together with the support shaft 33 about the shaft center 330.

The processing fluid supplier 40 is a mechanism for supplying a processing fluid to the upper surface of a substrate W held by the substrate holder 20. The processing fluid supplier 40 includes a top nozzle 41 and a bottom nozzle 42. As shown in FIGS. 1 and 2, the top nozzle 41 includes a nozzle arm 411, a nozzle head 412 provided at the tip of the nozzle arm 411, and a nozzle motor 413. The nozzle arm 411 is driven by the nozzle motor 413 and rotates in the horizontal direction about the root end of the nozzle arm 411. This makes the nozzle head 412 movable between a processing position located above a substrate W held by the substrate holder 20 (position indicated by chain double-dashed lines in FIG. 1) and a retracted position located outward of the processing fluid collector 50 (position indicated by solid lines in FIG. 1).

The nozzle head 412 is connected to a fluid supplier (not shown) for supplying a processing fluid. Examples of the processing fluid that is used include an SPM cleaning fluid (a mixed solution of sulfuric acid and a hydrogen peroxide solution), an SC-1 cleaning fluid (a mixed solution of aqueous ammonia, a hydrogen peroxide solution, and pure water), an SC-2 cleaning fluid (a mixed solution of hydrochloric acid, a hydrogen peroxide solution, and pure water), a DHF cleaning fluid (dilute hydrofluoric acid), and pure water (deionized water). When a valve of the fluid supplier is opened with the nozzle head 412 arranged at the processing position, the processing fluid supplied from the fluid supplier is ejected from the nozzle head 412 toward the upper surface of a substrate W held by the substrate holder 20.

The nozzle head 412 may be a so-called two-fluid nozzle that generates droplets by mixing a processing fluid and a pressurized gas and then ejects a mixed fluid of the droplets and a gas to a substrate W. Each processing unit 102 may include a plurality of top nozzles 41.

The bottom nozzle 42 is arranged inside a through hole provided in the center of the spin base 21. The bottom side nozzle 42 has an exhaust port that faces the lower surface of a substrate W held by the substrate holder 20. The bottom nozzle 42 is also connected to a fluid supplier for supplying a processing fluid. When the processing fluid is supplied from the fluid supplier to the bottom nozzle 42, the processing fluid is ejected from the bottom nozzle 42 toward the lower surface of a substrate W.

The processing fluid collector 50 is a part that collects a used processing fluid. As shown in FIG. 2, the processing fluid collector 50 includes an inner cup 51, an intermediate cup 52, and an outer cup 53. The inner cup 51, the intermediate cup 52, and the outer cup 53 can be moved up and down independently of one another between a raised position and a lowered position by an elevating mechanism, which is not shown, the raised position being a position at which the upper end portions of the cups are positioned above a substrate W, the lowered position being a position at which the upper end portions of the cups are positioned below a substrate W. In FIG. 2, the inner cup 51, the intermediate cup 52, and the outer cup 53 are all arranged at the lowered position.

The inner cup 51 includes a ring-shaped first guide plate 510 that encircles the surrounding of the substrate holder 20. The intermediate cup 52 includes a ring-shaped second guide plate 520 that is located outward and upward of the first guide plate 510. The outer cup 53 includes a ring-shaped third guide plate 530 that is located outward and upward of the second guide plate 520. The bottom of the inner cup 51 expands to under the intermediate cup 52 and the outer cup 53. This bottom has an upper surface in which a first drain groove 511, a second drain groove 512, and a third drain groove 513 are provided in order from the inside.

The processing fluid ejected from the top nozzle 41 and the bottom nozzle 42 of the processing fluid supplier 40 is supplied to a substrate W and then scattered outward by centrifugal force generated by rotation of the substrate W. Then, the processing fluid scattered from the substrate W is collected by one of the first guide plate 510, the second guide plate 520, and the third guide plate 530. In the case where the inner cup 51, the intermediate cup 52, and the outer cup 53 are all positioned at the raised position, the processing fluid scattered from the substrate W is collected by the first guide plate 510. The processing fluid collected by the first guide plate 510 is discharged through the first drain groove 511 to the outside of the processing unit 102. In the case where the inner cup 51 is positioned at the lowered position and the intermediate cup 52 and the outer cup 53 are positioned at the raised position, the processing fluid scattered from the substrate W is collected by the second guide plate 520. The processing fluid collected by the second guide plate 520 is discharged through the second drain groove 512 to the outside of the processing unit 102. In the case where the inner cup 51 and the intermediate cup 52 are positioned at the lowered position and the outer cup 53 is positioned at the raised position, the processing fluid scattered from the substrate W is collected by the third guide plate 530. The processing fluid collected by the third guide plate 530 is discharged through the third drain groove 513 to the outside of the processing unit 102.

In this way, the processing unit 102 includes a plurality of passages for discharging the processing fluid. Thus, the processing fluid supplied to the substrate W can be distinguished and collected depending on the type. Accordingly, other processing such as disposal or regeneration of a collected processing fluid can also be performed separately depending on the properties of the processing fluid.

The barrier plate 60 is a member for suppressing diffusion of a gas in the vicinity of the surface of a substrate W during some processing such as dry processing. The barrier plate 60 has a disk-like outside shape and is arranged horizontally above the substrate holder 20. As shown in FIG. 2, the barrier plate 60 is connected to an elevating mechanism 61. When the elevating mechanism 61 is operated, the barrier plate 60 moves up and down between an upper position spaced above from the upper surface of a substrate W held by the substrate holder 20 and a lower position closer to the upper surface of the substrate W than the upper position. For example, the elevating mechanism 61 may be a mechanism for converting rotational movements of a motor to translator movements by a ball screw.

The barrier plate 60 has an air outlet 62 that is provided in the center of the lower surface and through which a gas for drying (hereinafter, referred to as the “dry gas”) is issued. The air outlet 62 is connected to a gas supplier (not shown) that supplies the dry gas. The dry gas may, for example, be a heated nitrogen gas.

In the case where the processing fluid is supplied from the top nozzle 41 to a substrate W, the barrier plate 60 retracts to the upper position. In the case where processing for drying a substrate W is performed after the supply of the processing fluid, the elevating mechanism 61 lowers the barrier plate 60 to the lower position. Then, the dry gas is issued from the air outlet 62 toward the upper surface of the substrate W. At this time, the barrier plate 60 prevents diffusion of the gas. As a result, the dry gas is efficiently supplied to the upper surface of the substrate W.

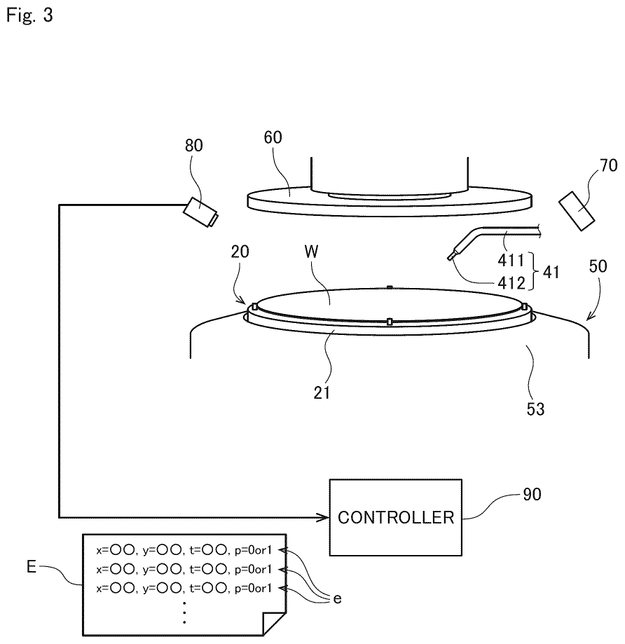

The irradiator 70 is a light source that applies pattern light having a light and dark pattern. For example, the irradiator 70 may be installed at a position diagonally spaced above from a substrate W held by the substrate holder 20. FIG. 3 is a perspective view of the substrate holder 20, the irradiator 70, and the event-based camera 80. As shown in FIG. 3, the irradiator 70 according to the present embodiment is installed diagonally downward toward the upper surface of the substrate W. The irradiator 70 applies the pattern light having a light and dark pattern toward the processing fluid supplied to the upper surface of the substrate W.

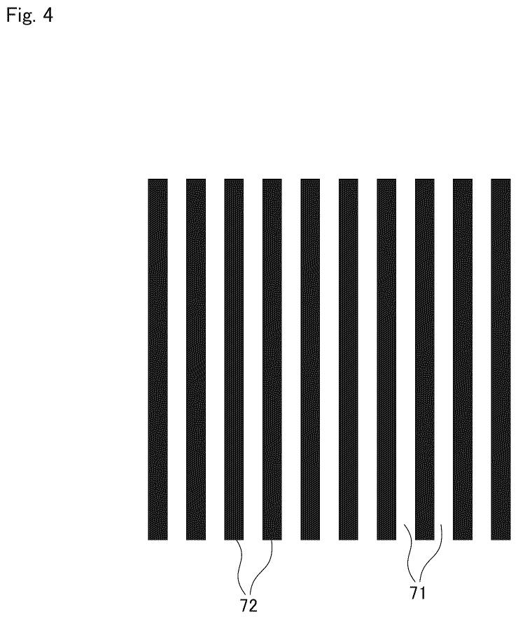

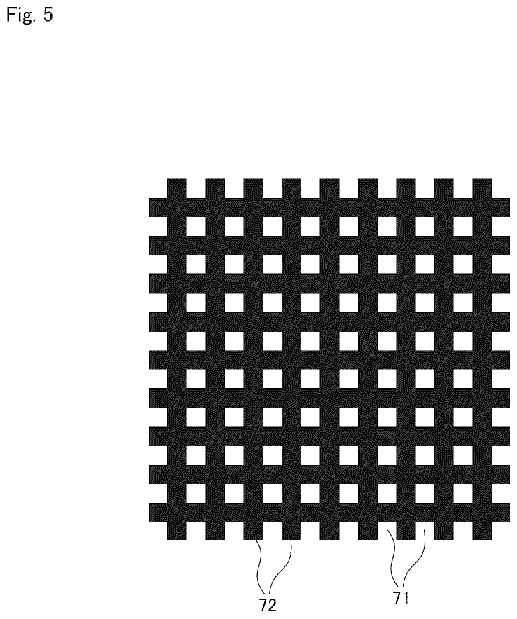

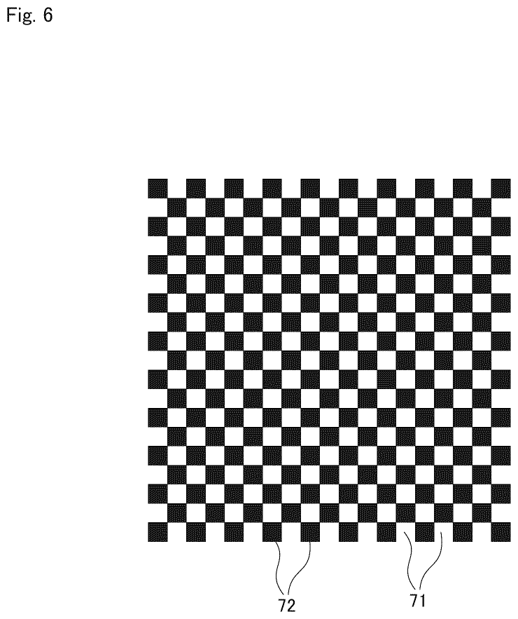

FIGS. 4 to 6 are diagrams showing examples of the light and dark pattern of the pattern light applied from the irradiator 70. As shown in FIGS. 4 to 6, the light and dark pattern includes a plurality of bright regions 71 and a plurality of dark regions 2 darker than the bright regions. For example, the light and dark pattern may be a line-and-space pattern as shown in FIG. 4, in which the bright regions 71 and the dark regions 72 are alternately and repeatedly aligned in one direction. The light and dark pattern may also be a grid pattern or a checkerboard pattern as shown in FIGS. 5 and 6, in which the bright regions 71 and the dark regions 72 are alternately and repeatedly aligned in two directions orthogonal to each other.

The event-based camera 80 is a device that captures an image of the processing fluid supplied to the upper surface of the substrate W. The event-based camera 80 is installed at a position spaced diagonally above from a substrate W held by the substrate holder 20. The event-based camera 80 is also arranged at a position opposite to the irradiator 70 with respect to the central axis of the substrate W. The event-based camera 80 is installed diagonally downward toward the upper surface of the substrate W. The event-based camera 80 captures an image of the processing fluid on the substrate W when the processing fluid is ejected from the nozzle head 412 toward the upper surface of the substrate W.

Common cameras for capturing moving images (frame-based cameras) output moving image data in which frame images including information about the luminance values of a large number of pixels are aligned in time sequence. In contrast, the event-based camera 80 outputs event data E that is configured by information only about pixels with changed luminance values. The event data E is configured by a plurality of single data pieces e that are generated only when luminance values have changed. As shown in FIG. 3, each single data piece e is configured by information including coordinates x and y of a pixel with a changed luminance value, the time t of change of the luminance value, and the direction p of change of the luminance value. The direction p of change of the luminance value takes a value of “1” when the luminance value has changed in the direction of increasing luminance, and takes a value of “0” when the luminance value has changed in the direction of reducing luminance.

In this way, the event-based camera 80 outputs information only about pixels with changed luminance values. Thus, the amount of information included in the event data E output from the event-based camera 80 is smaller than the amount of information included in the moving images output from a frame-based camera. Accordingly, the use of the event-based camera 80 allows higher-speed data acquisition and transfer than in the case of using a frame-based camera. The event-based camera 80 is also capable of acquiring the single data pieces e at shorter time intervals (e.g., every several microseconds) than the time intervals at which a frame-based camera acquires frame images. Therefore, the use of the event-based camera 80 enables capturing an image of high-speed motion of the processing fluid.

The event-based camera 80 transmits the event data E obtained by image capture to the controller 90.

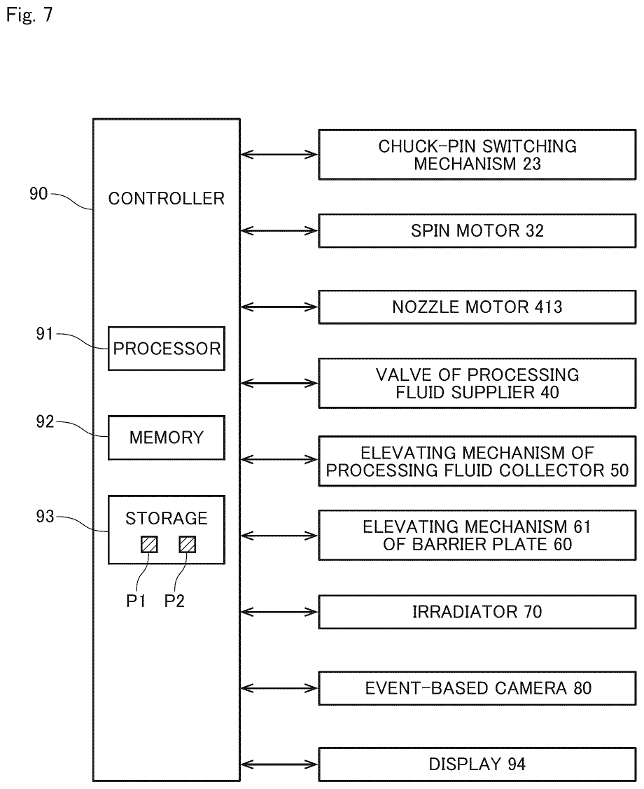

The controller 90 is means for controlling operations of each constituent element of the processing unit 102. FIG. 7 is a block diagram showing electrical connection between the controller 90 and each constituent element of the processing unit 102. As conceptually shown in FIG. 7, the controller 90 is configured as a computer that includes a processor 91 such as a CPU, memory 92 such as RAM, and a storage 93 such as a hard disk drive.

The storage 93 stores an operation control program P1 and a monitoring program P2. The operation control program P1 is a computer program for controlling the operations of each constituent element of the processing unit 102 in order to allow the processing unit 102 to perform processing on a substrate W. The monitoring program P2 is a computer program for monitoring and evaluating the fluid state of the processing fluid in the processing unit 102 in accordance with the event data E obtained from the event-based camera 80.

As shown in FIG. 7, the controller 90 is communicably connected via a cable or wirelessly to each of the above-described constituent elements including the chuck-pin switching mechanism 23, the spin motor 32, the nozzle motor 413, the valve of the processing fluid supplier 40, the elevating mechanism of the processing fluid collector 50, the elevating mechanism 61 of the barrier plate 60, the irradiator 70, and the event-based camera 80. The controller 90 is also electrically connected to a display 94 such as a liquid crystal display. The controller 90 controls the operations of each constituent element described above in accordance with the operation control program P1 and the monitoring program P2 which are stored in the storage 93. Accordingly, processing in steps S1 to S5 and S11 to S14 described below proceeds.

### 3. Operations of Substrate Processing Apparatus

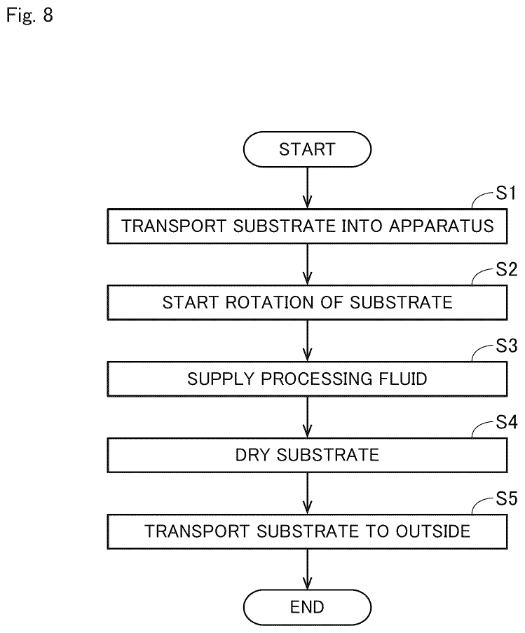

Next description is given of the processing to be performed on a substrate W in the above-described processing unit 102. FIG. 8 is a flowchart showing the procedure of the processing that is performed on a substrate W.

In the case of processing a substrate W in the processing unit 102, first, the main transport robot 103 transports the substrate W to be processed into the chamber 10 (step S1). The substrate W transported into the chamber 10 is held horizontally by the chuck pins 22 of the substrate holder 20. After this, the spin motor 32 of the rotation mechanism 30 is driven to start rotation of the substrate W (step S2). Specifically, the substrate W held by the support shaft 33, the spin base 21, and the chuck pins 22 rotate about the shaft center 330 of the support shaft 33.

Then, the processing fluid is supplied from the processing fluid supplier 40 (step S3). In step S3, the nozzle motor 413 is driven so as to move the nozzle head 412 to the processing position facing the upper surface of the substrate W. Then, the processing fluid is ejected from the nozzle head 412 positioned at the processing position. The storage 93 of the controller 90 has parameters stored in advance, such as the speed and time of ejection of the processing fluid. The controller 90 performs the operation of ejecting the processing fluid from the top nozzle 41 in accordance with the above settings.

In step S3, the top nozzle 41 may rock in the horizontal direction at the processing position while ejecting the processing fluid. As necessary, a processing fluid may also be ejected from the bottom nozzle 42.

During the process of supplying the processing fluid in step S3, the barrier plate 60 is positioned at the upper position above the top nozzle 41. When the supply of the processing fluid to the substrate W is completed and the top nozzle 41 is positioned at the retracted position, the controller 90 operates the elevating mechanism 61 so as to move the barrier plate 60 from the upper position to the lower position. Then, the number of revolutions of the spin motor 32 is increased to increase the speed of rotation of the substrate W, and the dry gas is issued toward the substrate W from the air outlet 62 provided in the lower surface of the barrier plate 60. In this way, the surface of the substrate W is dried (step S4).

When the processing for drying the substrate W ends, the spin motor 32 is stopped so as to stop the rotation of the substrate W. Then, the hold of the substrate W by the chuck pins 22 is released. Thereafter, the main transport robot 103 takes out the processed substrate W from the substrate holder 20 and transports the processed substrate W to the outside of the chamber 10 (step S5).

Each processing unit 102 repeatedly performs the above-described processing in step S1 to S5 on a plurality of substrates W transported in sequence.

### 4. Monitoring Processing

In step S3 described above, the substrate processing apparatus 100 according to the present embodiment monitors whether the fluid state of the processing fluid is normal while supplying the processing fluid to the upper surfaces of substrates W. This monitoring processing is described hereinafter.

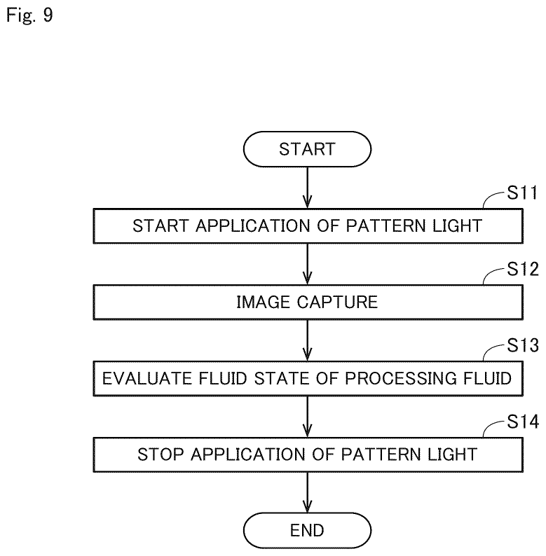

FIG. 9 is a flowchart showing the procedure of the monitoring processing. In the monitoring processing, first, the controller 90 starts to apply pattern light from the irradiator 70 as shown in FIG. 9 (step S11). The processing fluid is ejected from the nozzle head 412 to the vicinity of the center of the upper surface of a substrate W and flows from the center of the substrate W to the periphery thereof along the upper surface of the substrate W. The irradiator 70 applies the pattern light having a light and dark pattern toward the processing fluid flowing on the upper surface of the substrate W.

Then, the controller 90 causes the event-based camera 80 to capture an image (step S12). That is, while the processing fluid is supplied to the substrate W and the pattern light is applied to the processing fluid, the event-based camera 80 captures an image of the processing fluid on the substrate W. The event-based camera 80 generates event data E by image capture. Then, the event-based camera 80 outputs the generated event data E to the controller 90. The controller 90 stores the event data E output from the event-based camera 80 in the storage 93.

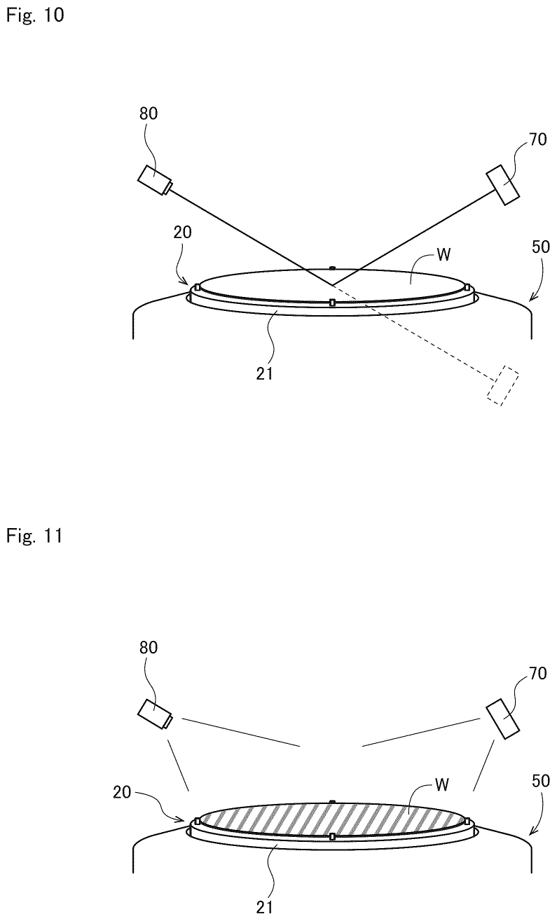

FIGS. 10 and 11 are diagram showing image capture by the event-based camera 80. In the example shown in FIG. 10, the event-based camera 80 is arranged on the side opposite to the irradiator 70 with the central axis of the substrate W sandwiched in between. The focus of the event-based camera 80 is adjusted not to the upper surface of the substrate W, but to a reflected position of the irradiator 70 on the surface of the processing fluid on the substrate W (displayed with broken lines in FIG. 10). This allows the event-based camera 80 to capture a reflected image of the irradiator 70 reflected on the surface of the processing fluid. That is, the event-based camera 80 is capable of capturing an image of the processing fluid supplied to the upper surface of the substrate W together with a reflected image of the pattern light.

Meanwhile, in the example shown in FIG. 11, the focus of the event-based camera 80 is adjusted to the position of the surface of the processing fluid on the substrate W. This allows the event-based camera 80 to capture a projected image of the pattern light projected on the surface of the processing fluid. That is, the event-based camera 80 is capable of capturing an image of the processing fluid supplied to the upper surface of the substrate W together with a projected image of the pattern light.

In the case where the object to be processed is a semiconductor wafer, a projected image is difficult to appear on the processing fluid on the substrate W because the substrate W has a mirror surface. In such a case, the event-based camera 80 may capture a reflected image of the pattern light as shown in FIG. 10. Meanwhile, in the case where the pattern light is difficult to be reflected on the surface of the processing fluid, the event-based camera 80 may capture a projected image of the pattern light as shown in FIG. 11. In the case of capturing the reflected image as shown in FIG. 10, the event-based camera 80 has to be arranged at a position at which regular reflection of the pattern light can be received. In contrast, in the case of capturing the projected image as shown in FIG. 11, the event-based camera 80 does not necessarily have to be arranged at a position at which regular reflection can be received. This increases the degree of flexibility in the arrangement of the event-based camera 80.

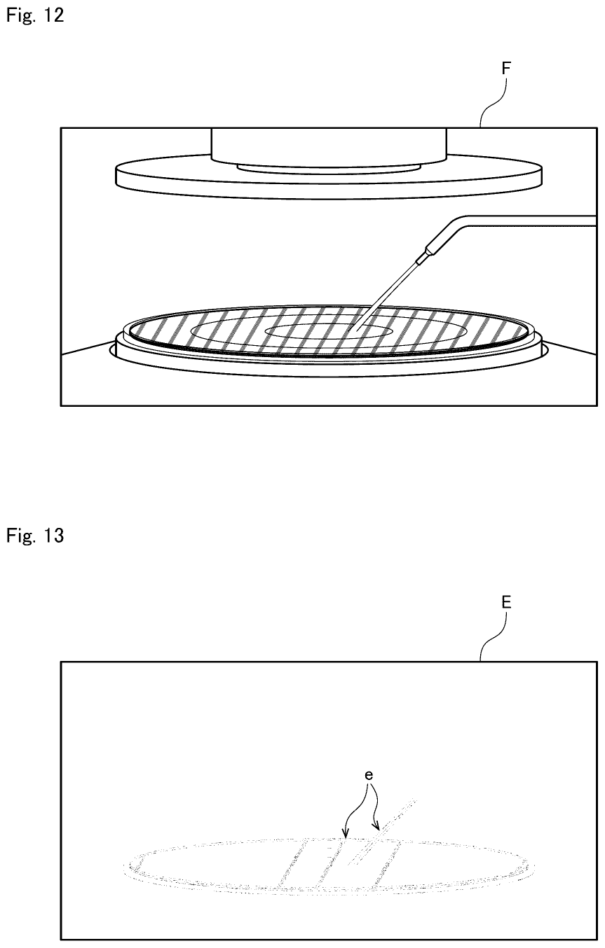

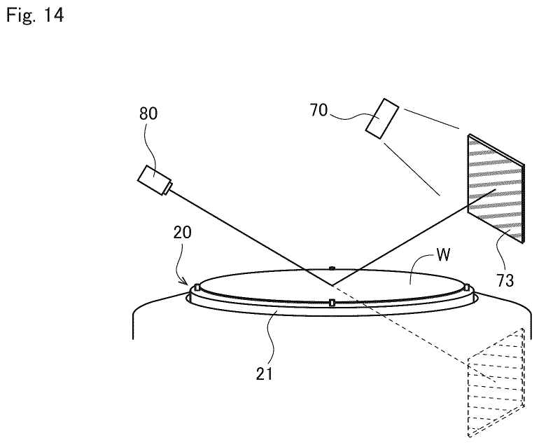

FIG. 12 is a diagram showing an example of a frame image F when an image of a substrate W to which the processing fluid is supplied is captured by a normal frame-based camera. FIG. 13 is a diagram showing an example in which an image of the substrate W to which the processing fluid is supplied is captured by the event-based camera 80, and obtained event data E is imaged. In FIG. 13, pixels whose single data pieces e are in the event data E are indicated by black dots.

The normal frame image F defines a luminance value for every pixel. Thus, portions with no movements also appear as images in the normal frame image F as shown in FIG. 12. In contrast, the event data E is configured by information only about pixels with changed luminance values. Thus, the event data E includes single data pieces e for only portions with movements and does not include single data pieces e for portions with no movements as shown in FIG. 13.

The controller 90 evaluates, on the basis of the event data E, whether the fluid state of the processing fluid is normal (step S13). For example, the controller 90 may store event data E obtained under normal conditions (e.g., at the time of shipment of the apparatus) as reference data. Then, the controller 90 may compare the event data E acquired in step S12 with the reference data to determine whether the fluid state of the processing fluid is normal. More specifically, the controller 90 may determine the occurrence of anomalies when a difference of the event data E acquired in step S12 from the aforementioned reference data exceeds a preset tolerance. This allows detection of anomalies such as undulations of the liquid level of the processing fluid on the upper surface of the substrate W or breaks of a liquid membrane on the upper surface of the substrate W (exposure of the surface of the substrate).

When ending the monitoring processing, the controller 90 stops the application of the pattern light from the irradiator 70 (step S14).

As described above, the substrate processing apparatus 100 applies the pattern light to the processing fluid supplied to the upper surface of a substrate W. Thus, disturbance in the fluid state of the processing fluid also causes disturbance in the image of the pattern light. Accordingly, it is possible, by capturing an image of the pattern light, to detect minute changes in the fluid state of the processing fluid on the basis of distortion of the pattern light. In particular, although, in the case where the processing fluid is colorless and transparent, it is difficult to capture an image of the processing fluid itself, image capture of the pattern light allows indirect detection of the fluid state of the processing fluid.

In the case where the processing fluid is supplied at high speed, it is difficult to capture an image of high-speed motion by an ordinary frame-based camera. However, the use of the event-based camera 80 as in the above-described embodiment allows image capture of high-speed motion of the processing fluid. Besides, since the event data E acquired by the event-based camera 80 is data only about pixels with changed luminance values, there is no need to separately perform processing for extracting locations where the image of the pattern light has changed. This reduces the number of processing steps included in the monitoring processing.

### 5. Variations

While one embodiment of the present invention has been described thus far, the present invention is not intended to be limited to the above-described embodiment.

### 5-1. First Variation

FIG. 14 is a diagram showing image capture according to a first variation. In the example shown in FIG. 14, each processing unit 102 has a projection surface 73 different from the surface of the substrate W. The projection surface 73 is located sideway above the substrate W held by the substrate holder 20. The projection surface 73 may, for example, be a white flat surface other than a mirror surface. The irradiator 70 applies the pattern light toward the projection surface 73. Accordingly, the pattern light is projected on the projection surface 73. The event-based camera 80 captures a reflected image of the projection surface 73 reflated on the surface of the processing fluid on the substrate W (displayed with broken lines in FIG. 14) in step S12.

Even in such a mode, it is possible to image the processing fluid together with the pattern light. Accordingly, it is possible to detect minute changes in the fluid state of the processing fluid on the basis of distortion of the pattern light. In the example shown in FIG. 14, there is no need to arrange the irradiator 70 at the position of regular projection with respect to the event-based camera 80. The irradiator 70 may be arranged at any position as long as it is possible to project the pattern light on the projection surface 73. Therefore, adopting the mode shown in FIG. 14 increases the degree of flexibility in the arrangement of the irradiator 70.

### 5-2. Other Variations

In the embodiment described above, the event-based camera 80 is used to capture images of the processing fluid and the pattern light. Alternatively, a high-sensitivity frame-based camera that is capable of high-speed image capture may be used, instead of the event-based camera 80. Even in the case of using a frame-based camera, it is possible, by imaging the processing fluid together with the pattern light, to detect more minute changes in the fluid state of the processing fluid than in the case of not using the pattern light. However, in the case of using a frame-based camera, it becomes necessary to separately perform image processing for extracting portions that have changed from the captured image.

The above embodiment describes a case of supplying the processing fluid to the surfaces of semiconductor wafers serving as substrates W. However, the present invention is also applicable to a case of monitoring the fluid state of a processing fluid that is supplied to objects to be processed other than semiconductor wafers.

It is, however, noted that, in apparatuses that supply a processing fluid to substrates W for precision electronic component such as semiconductor wafers, extreme precision is needed to manage the fluid state of the processing fluid. Thus, the importance of applying the monitoring method according to the present invention is especially high in apparatuses that supply a processing fluid to substrates W.

### REFERENCE SIGNS LIST

10 chamber
20 substrate holder
30 rotation mechanism
40 processing fluid supplier
41 top nozzle
50 processing fluid collector
60 barrier plate
70 irradiator
71 bright region
72 dark region
73 projection surface
80 event-based camera
90 controller
100 substrate processing apparatus
101 indexer
102 processing unit
103 main transport robot
E event data
F frame image
P1 operation control program
P2 monitoring program
W substrate

1. A monitoring method for monitoring a processing unit that supplies a processing fluid to an object to be processed, the monitoring method comprising:
a) capturing an image of the processing fluid while supplying the processing fluid to the object to be processed; and
b) evaluating a fluid state of the processing fluid in accordance with a result of image capture in the operation a),
wherein, in the operation a), pattern light having a light and dark pattern is applied to capture a reflected image or projected image of the pattern light on the surface of the processing fluid.

2. The monitoring method according to claim 1, wherein
in the operation a), the image of the processing fluid is captured by an event-based camera to acquire event data configured by information only about a pixel with a changed luminance value, and
in the operation b), the fluid state of the processing fluid is evaluated based on the event data.

3. The monitoring method according to claim 1, wherein
in the operation a), the reflected image of the pattern light reflected on the surface of the processing fluid is captured.

4. The monitoring method according to claim 1, wherein
in the operation a), the projected image of the pattern light projected on the surface of the processing fluid is captured.

5. The monitoring method according to claim 1, wherein
in the operation a), the pattern light is applied to a projection surface that is different from the object to be processed, to capture the reflected image of the projection surface reflected on the surface of the processing fluid.

6. The monitoring method according to claim 1, wherein
the light and dark pattern is a pattern in which a bright region and a dark region are alternately and repeatedly aligned in one direction.

7. The monitoring method according to claim 1, wherein
the light and dark pattern includes a pattern in which a bright region and a dark region are alternately and repeatedly aligned in two directions orthogonal to each other.

8. The monitoring method according to claim 1, wherein
the object to be processed is a semiconductor wafer.

9. A manufacturing apparatus comprising:
a nozzle from which a processing fluid is supplied to an object to be processed;
an irradiator that applies pattern light having a light and dark pattern;
a camera that captures an image of the processing fluid supplied from the nozzle to the object to be processed; and
a computer communicably connected to the camera,
wherein the irradiator applies the pattern light, and the camera captures a reflected image or projected image of the pattern light on the surface of the processing fluid, and
the computer evaluates a fluid state of the processing fluid in accordance with a result of image capture by the camera.
